(19) United States
(12) Patent Application Publication
(10) Pub. No.: US 2013/0043601 A1
(43) Pub. Date: Feb. 21, 2013

(54) UNIVERSAL PRINTED CIRCUIT BOARD AND MEMORY CARD INCLUDING THE SAME

(71) Applicants: Seok-Joon MOON, Suwon-si (KR); In-Jae Lee, Anyang-si (KR); So-Young Jung, Seongnam-si (KR)

(72) Inventors: Seok-Joon MOON, Suwon-si (KR); In-Jae Lee, Anyang-si (KR); So-Young Jung, Seongnam-si (KR)

(21) Appl. No.: 13/565,451

(22) Filed: Aug. 2, 2012

(30) Foreign Application Priority Data
Aug. 16, 2011 (KR) 10-2011-0081360

(51) Int. Cl. H01L 23/48

(52) U.S. Cl. 257/777; 257/E23.01

(57) ABSTRACT

Disclosed is a memory card which includes a universal PCB including a first pad group and a second pad group, the first and second pad groups being connected to each other via one or more PCB wires, a first semiconductor chip electrically connected with at least one pad of the first pad group via a first bonding wire, and a second semiconductor chip electrically connected with at least one pad of the second pad groups via a second bonding wire, wherein the first bonding wire or the second bonding wire is changed according to a combination of the first and second semiconductor chips without a change in the PCB wires.

### CROSS-REFERENCE TO RELATED APPLICATIONS

This application claims the benefits, under 35 U.S.C §119, of Korean Patent Application No. 10-2011-0081360 filed Aug. 16, 2011, the entirety of which is incorporated by reference herein.

### BACKGROUND

Exemplary embodiments relate to a semiconductor device, and more particularly to a printed circuit board used for a semiconductor chip package and a memory card including the same.

A hand-held electronic device, such as a smart phone, a tablet PC, a digital camera, an MP3 player, or a PDA, often includes a nonvolatile memory card, such as a Compact Flash (CF) card, a Secure Digital (SD) card, a micro SD card, a memory stick, or an XD-Picture card.

A memory card includes a memory chip for storing data, a controller chip for controlling the memory chip, and a printed circuit board (PCB) on which the memory chip and the controller chip are mounted. The design of a PCB may change depending on size, capacity, chip pad type, or arrangement of chips to be mounted on the PCB. Accordingly, there is a need of a memory card having a universal type PCB which undergoes no design change irrespective of the type of chips.

### SUMMARY

An embodiment of the inventive concept provides a memory card which includes a printed circuit board (PCB) including a first pad group having a plurality of pads, a second pad group having a plurality of pads, and a PCB wire connecting the first pad group with the second pad group, a first bonding wire connecting a pad of a first semiconductor chip of a first type with one of the plurality of pads of the first pad group or connecting a pad of a second semiconductor chip of a second type with another pad of the plurality of the first pad group, wherein the first type is different from the second type, and a second bonding wire connecting a pad of a third semiconductor chip of a third type with one of the plurality of pads of the second pad group.

An embodiment of the inventive concept provides a printed circuit board which includes a first pad group having a plurality of pads, a second pad group having a plurality of pads, a printed circuit board (PCB) connection unit connecting the first pad group with the second pad group, a first bonding wire connecting a pad of a first semiconductor chip of a first type with one of the plurality of pads of the first pad group or connecting a pad of a second semiconductor chip of a second type with another pad of the plurality of pads of the first pad group, wherein the first type is different from the second type, and a second bonding wire connecting a pad of a third semiconductor chip of a third type with one of the plurality of pads of the second pad group.

### BRIEF DESCRIPTION OF THE FIGURES

The embodiments will become apparent from the following description with reference to the following figures, wherein:

FIG. 1 is a block diagram schematically illustrating a memory card according to an exemplary embodiment of the inventive concept;

FIG. 2 is a block diagram illustrating a universal PCB as illustrated in FIG. 1;

FIG. 3 is a diagram illustrating a first pad group as illustrated in FIG. 2 according to an exemplary embodiment of the inventive concept;

FIG. 4 is a diagram illustrating a first pad group as illustrated in FIG. 2 according to an exemplary embodiment of the inventive concept;

FIG. 5 is a diagram illustrating a first pad group as illustrated in FIG. 2 according to an exemplary embodiment of the inventive concept;

FIG. 6 is a diagram illustrating a PCB connection unit according to an exemplary embodiment of the inventive concept;

FIG. 7 is a diagram illustrating a PCB connection unit according to an exemplary embodiment of the inventive concept;

FIGS. 8 and 9 are diagrams schematically illustrating wire bonding between a nonvolatile memory chip and a second pad group according to an exemplary embodiment of the inventive concept;

FIGS. 10 and 11 are diagrams schematically illustrating a wire bonding manner and a second pad group according to a mounting type of a nonvolatile memory chip;

FIGS. 12 and 13 are diagrams schematically illustrating a second pad and a wire bonding manner according to a mounting type of nonvolatile memory chips;

FIGS. 14 to 16 are diagrams illustrating applicable examples of a universal PCB technique according to a mounting condition of a nonvolatile memory chip;

FIG. 17 is a flowchart for describing a memory card fabricating process according to an exemplary embodiment of the inventive concept; and

FIG. 18 is a diagram schematically illustrating a computing system including a memory card according to an exemplary embodiment of the inventive concept.

### DETAILED DESCRIPTION

The embodiments of the inventive concept are described in more detail hereinafter with reference to the accompanying drawings. This inventive concept may, however, be embodied in many different forms and should not be construed as limited to the embodiments set forth herein. In the drawings, the size and relative sizes of layers and regions may be exaggerated for clarity. Like numbers may refer to like or similar elements throughout the specification and the drawings.

As used herein, the singular forms “a”, “an” and “the” are intended to include the plural forms as well, unless the context clearly indicates otherwise.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present.

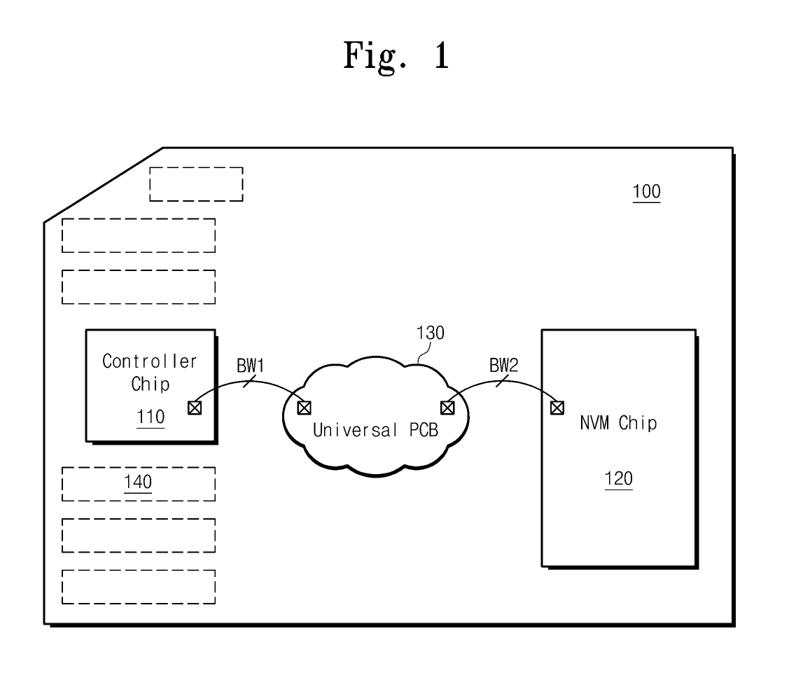

FIG. 1 is a block diagram schematically illustrating a memory card according to an exemplary embodiment of the inventive concept. Referring to FIG. 1, a memory card 100 includes a controller chip 110, a nonvolatile memory chip 120, and a universal PCB 130.

The controller chip 110 is configured to control the nonvolatile memory chip 120 in response to a command or a control signal from an external device. The controller chip 110 provides an interface between an external host and the nonvolatile memory chip 120. The controller chip 110 writes data from the host in the nonvolatile memory chip 120 in response to a write command from the host. The controller chip 110 controls a read operation of the nonvolatile memory chip 120 in response to a read command from the host. The controller chip 110 is configured to communicate with an external device (e.g., a host) via one of various interface protocols, such as USB, MMC, PCI-E, SAS, SATA, PATA, SCSI, ESDI, IDE, and the like.

The nonvolatile memory chip 120 includes one or more nonvolatile memory devices. For example, the nonvolatile memory chip 120 is formed of a NAND flash memory with a mass storage capacity. Alternatively, the nonvolatile memory chip 120 can be formed of a NOR flash memory or a next-generation nonvolatile memory, such as PRAM, MRAM, ReRAM, or FRAM.

The universal PCB 130 provides electrical connection between the controller chip 110 and the nonvolatile memory chip 120. The universal PCB 130 is used without design modification of PCB wiring on various combinations of the controller chip 110 and the nonvolatile memory chip 120. Various types of PCB wiring are designed separately according to product combinations due to functions, pad structures, integration, or chip sizes of the controller chip 110 and the nonvolatile memory chip 120. According to an embodiment, the universal PCB 130 provides a compatible mounting circumstance with respect to combinations of the control chip 110 and the nonvolatile memory chip 120. For example, various combinations of the control chip 110 and the nonvolatile memory chip 120 can be mounted on the universal PCB 130, with bonding wires BW1 and BW2 adjusted without modification of the PCB wiring.

The universal PCB 130 according to an exemplary embodiment of the inventive concept provides electrical connection between external signal contact (ESC) terminals 140 and the controller chip 110. The ESC terminals 140 are electrically connected with the controller chip 110 via the universal PCB 130. The ESC terminals 140 include metal lines that are extended from a terminal for connection with a host and that are connected with the universal PCB 130. The universal PCB 130 will be described below in greater detail.

The memory card according to an exemplary embodiment of the inventive concept has been schematically described. Once designed, the universal PCB 130 can be used, without changes to its design, for a combination between a controller chip different, e.g., in type, from the controller chip 110 and a nonvolatile memory chip different, e.g., in type, from the nonvolatile memory chip 120. Thus, costs for designing PCBs for memory cards and time taken to produce the memory cards can decrease.

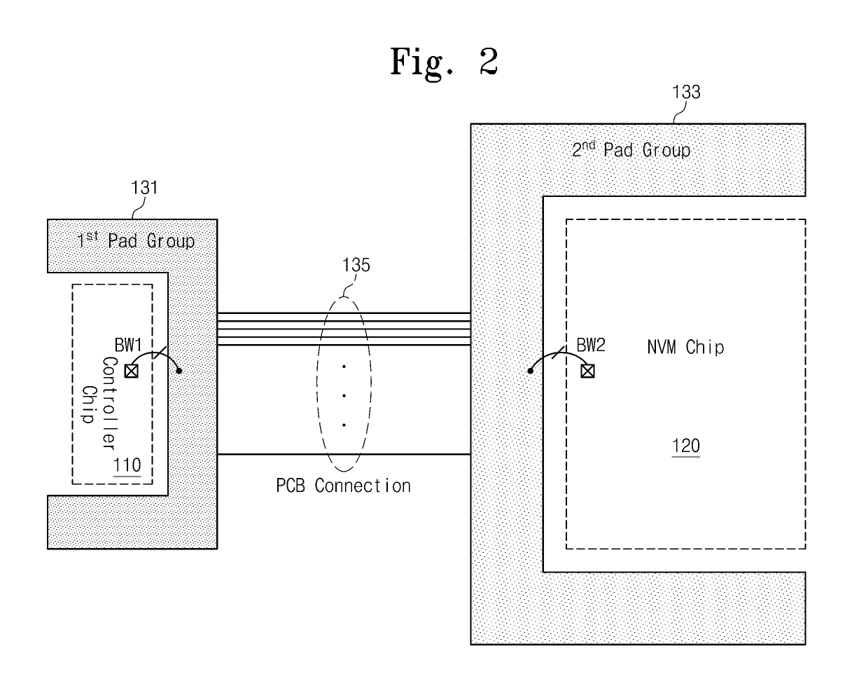

FIG. 2 is a block diagram illustrating a universal PCB as illustrated in FIG. 1. Referring to FIG. 2, the universal PCB 130 includes a first pad group 131, a second pad group 133, and a PCB connection unit 135.

The first pad group 131 is formed to surround a controller chip 110. The first pad group 131 includes an extended line of an ESC terminal 140 (refer to FIG. 1). According to an embodiment, a control signal or data provided from a host via the ESC terminal 140 is transferred to the controller chip 110 via pads which are formed within the first pad group 131 or directly to the controller chip 110 without passing through separate pads.

The first pad group 131 includes a plurality of pads which transfer control signals and data exchanged between the controller chip 110 and the nonvolatile memory chip 120. Pads of the first pad group 131 are connected to chip pads of the controller chip 110 via a boding wire BW1. According to an embodiment, electrical connection between the first pad group 131 and the controller chip 100 is reconfigured or rearranged through various connections of bonding wires (not shown) within the first pad group 131. Accordingly, although the PCB connection unit 135 between the first pad group 131 and the second pad group 133 remains unchanged, e.g., in structure or design, various electrical connection structures can be implemented by changing connections of the bonding wire BW1 and bonding wires of the first pad group 131.

For purposes of illustration, the first pad group 131 has a ‘C’ shape, but the embodiments of the inventive concept are not limited thereto. For example, according to an embodiment, a plurality of pads included in the first pad group 131 can be formed to have a bonding pad shape, an shape, or a bar shape.

The second pad group 133 is formed to surround the nonvolatile memory chip 120. The second pad group 133 is electrically connected with the first pad group 131 via the PCB connection unit 135. Pads included in the second pad group 133 include dummy pads which are not connected with pads of the first pad group 131.

A high-density memory card may be implemented by stacking a plurality of nonvolatile memory chips. According to an embodiment, the second pad group 133 is formed such that a plurality of chips exchange data with the controller chip 110 via one or more input/output channel. According to an embodiment, when nonvolatile memory chips are connected with the controller chip 110 via different channels, the nonvolatile memory chips include no or few electrically shared chip pads.

A plurality of nonvolatile memory chips can be connected with the controller chip 110 via one channel. Among chip pads of the nonvolatile memory chips, control signal pads with the same function or input/output pads with the same number are shared with a pad of the second pad group 133. For example, any one pad of the second pad group 133 is electrically connected with chip pads having the same function, the chip pads included in each of the nonvolatile memory chips.

The second pad group 133 according to an exemplary embodiment of the inventive concept provides a compatible electrical connection structure through reconfiguration/rearrangement of a bonding wire BW2 or through various channel configurations although the nonvolatile memory chip 120 includes a single chip or multiple chips.

The PCB connection unit 135 provides electrical connection between the first pad group 131 and the second pad group 133. The PCB connection unit 135 provides electrical connection with all pads of the first pad group 131 which are formed to exchange electrical signals with the second pad group 133. The PCB connection unit 135 may be designed to receive signal lines, data lines, and control lines provided between the first and second pad groups 131 and 133. Accordingly, a layout of the PCB connection unit 135 can remain unchanged.

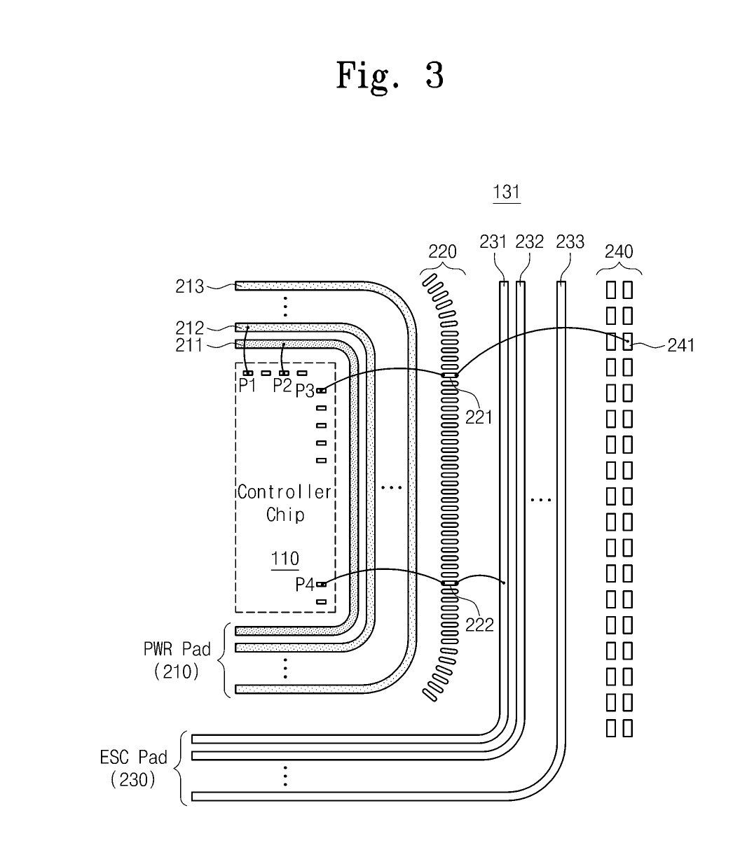

FIG. 3 is a diagram illustrating a first pad group as illustrated in FIG. 2 according to an exemplary embodiment of the inventive concept. Referring to FIG. 3, the first pad group 131 includes power pads 210, bonding pads 220, ESC pads 230, and rearrangement pads 240.

Through the power pads 210, power is supplied to a controller chip 110. For example, a power supply voltage VDD or a ground voltage VSS is supplied to the controller chip 110 via the power pads 210. Voltages regulated within a memory card 100 are supplied to the controller chip 110 via the power pads 210. For example, a first power pad 211 is electrically connected with a chip pad P2 of the controller chip 110 through wire bonding, and a second power pad 212 is electrically connected with a chip pad P1 of the controller chip 110 through wire bonding. According to an embodiment, more power pads, such as a power pad 213, may be provided. Various levels of voltages are provided to the controller chip 110 through wire bonding between the power pads 210 and chip pads. It is possible to improve the power integrity of the controller chip 110 by enlarging an area of the power pads 210.

The bonding pads 220 are disposed between the ESC pads 230 and the controller chip 110 or between the rearrangement pads 240 and the controller chip 110. The bonding pads 220 are formed to solve a problem associated with a length of a bonding wire between the ESC pads 230 and the controller chip 110 or between the rearrangement pads 240 and the controller chip 110. For example, when the bonding wire is excessively long, the reliability of a packaging process decreases. Wire bonding can be performed together with formation of the bonding pads 220. The bonding pads 220 connect the ESC pads 230 or the rearrangement pads 240 to the chip pads (e.g., P3 or P4) in the shortest distance.

The ESC pads 230 are extended from ESC terminals 140 as illustrated in FIG. 1. The ESC pads 230 are formed to exchange signals between an external device and the controller chip 110. The ESC pads 230 are disposed between the bonding pads 220 and the rearrangement pads 240. A pad 231 of the ESC pads 230 is connected with a pad 222 included in the bonding pads 220 via a wire. The pad 222 is electrically connected with a chip pad P4 of the controller chip 110. For purposes of illustration, electrical connection is made by one signal line. However, according to an embodiment, the connecting method also applies to the remaining pads 232 and 233 of the ESC pads 230.

The rearrangement pads 240 are connected with bonding wires extended from the bonding pads 220. For example, a pad 241 of the rearrangement pads 240 is connected with a pad 221 of the bonding pads 220 via a bonding wire. The pad 221 is electrically connected with the chip pad P3 via a bonding wire. The pad 241 is connected with any pad of a nonvolatile memory chip 120 via a PCB connection unit 135.

The rearrangement pads 240 electrically connect the controller chip 110 and the nonvolatile memory chip 120. According to an embodiment, a bonding wire for connection between the rearrangement pads 240 and the bonding pads 220 is optionally adjusted. According to an embodiment, wire bonding of the bonding pads 220 is limited by an arrangement order of chip pads P1 to P4 of the controller chip 110, but wire bonding of the rearrangement pads is not limited by the arrangement order of the chip pads P1 to P4. Various chip combinations can be adopted by adjusting arrangement of bonding wires between the rearrangement pads 240 and the bonding pads 220.

For purposes of illustration, two columns of rearrangement pads 240 are provided. However, the embodiments of the inventive concept are not limited thereto. According to an embodiment, a single column of rearrangement pads 240 is provided. Alternatively, three or more columns of rearrangement pads 240 are provided. According to an embodiment, a bonding wire may be arranged in various manners between a pad in a column of the rearrangement pads 240 and a pad in another column of the rearrangement pads 240.

For purposes of illustration, the power pads 210 are formed to have a ‘U’ shape. However, the embodiments of the inventive concept are not limited thereto. According to an embodiment, the power pads 210 can be formed to have various shapes, such as a bonding pad shape, an V shape, a ring shape, or a bar shape.

The power pads 210 are not limited to supplying power. Locations of the bonding pads 220 or the ESC pads 230 are not limited to those described above in connection with FIG. 3. According to an embodiment, the pads 210, 220, and 230 are positioned to have an arrangement order or locations different from those described above in connection with FIG. 3.

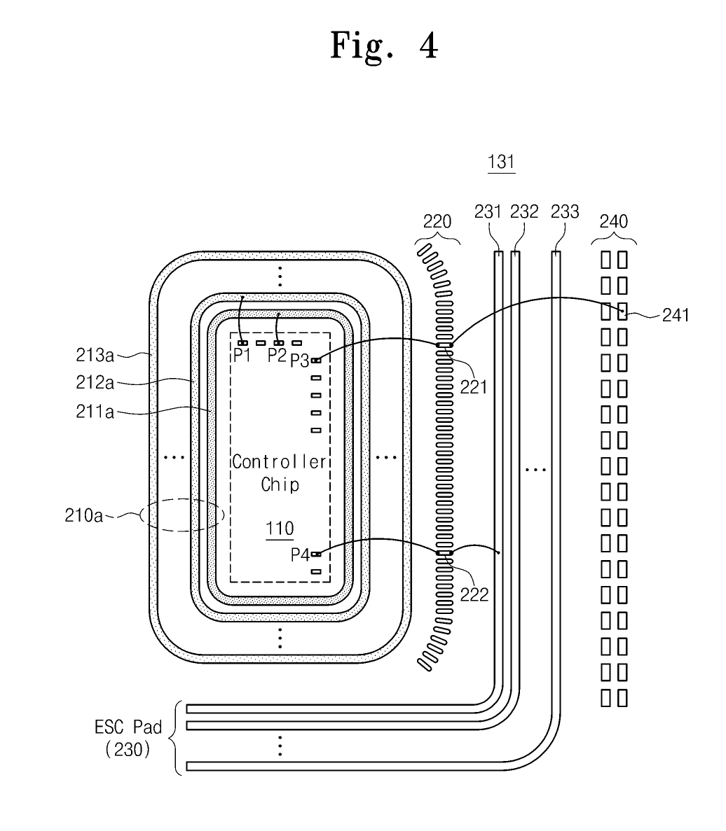

FIG. 4 is a diagram illustrating a first pad group as illustrated in FIG. 2 according to an exemplary embodiment of the inventive concept. Referring to FIG. 4, the first pad group 131 includes power pads 210a with a ring shape, bonding pads 220, ESC pads 230, and rearrangement pads 240.

Through the power pads 210a, power is supplied to a controller chip 110. For example, a power supply voltage VDD or a ground voltage VSS is supplied to the controller chip via the power pads 210a. A first power pad 211a is electrically connected with a chip pad P2 of the controller chip 110 through wire bonding, and a second power pad 212a is electrically connected with a chip pad P1 of the controller chip 110 through wire bonding. According to an embodiment, more power pads, such as a power pad 213a, may be provided. Various levels of voltages are provided to the controller chip 110 through wire bonding between the power pads 210a and chip pads. The ring-shaped power pads 210a enables stable supply of power regardless of the type of chip pads of the controller chip 110.

The bonding pads 220 are disposed between the ESC pads 230 and the controller chip 110 or between the rearrangement pads 240 and the controller chip 110. The bonding pads 220 are formed to solve a problem associated with a length of a bonding wire between the ESC pads 230 and the controller chip 110 or between the rearrangement pads 240 and the controller chip 110. For example, when the bonding wire is excessively long, the reliability of a packaging process decreases. Wire bonding can be performed together with formation of the bonding pads 220. The bonding pads 220 connect the ESC pads 230 or the rearrangement pads 240 to the chip pads (e.g., P3 or P4) in the shortest distance.

The ESC pads 230 are extended from ESC terminals 140 as illustrated FIG. 1. The ESC pads 230 are formed to exchange signals between an external device and the controller chip 110. The ESC pads 230 are disposed between the bonding pads 220 and the rearrangement pads 240. A pad 231 of the ESC pads 230 is connected with a pad 222 included in the bonding pads 220 via a wire. The pad 222 is electrically connected with a chip pad P4 of the controller chip 110. For purposes of illustration, electrical connection is made by one signal line. However, according to an embodiment, the connecting method also applies to the remaining pads 232 and 233 of the ESC pads 230.

The rearrangement pads 240 are connected with bonding wires extended from the bonding pads 220. For example, a pad 241 of the rearrangement pads 240 is connected with a pad 221 of the bonding pads 220 via a bonding wire. The pad 221 is electrically connected with the chip pad P3 via a bonding wire. The pad 241 is connected with any pad of a nonvolatile memory chip 120 via a PCB connection unit 135.

The rearrangement pads 240 electrically connect the controller chip 110 and the nonvolatile memory chip 120. According to an embodiment, a bonding wire for connection between the rearrangement pads 240 and the bonding pads 220 is optionally adjusted. According to an embodiment, wire bonding of the bonding pads 220 is limited by an arrangement order of chip pads P1 to P4 of the controller chip 110, and wire bonding of the rearrangement is not limited by the arrangement order of the chip pads P1 to P4. Various chip combinations can be adopted by adjusting arrangement of bonding wires between the rearrangement pads 240 and the bonding pads 220.

For purposes of illustration, two columns of rearrangement pads 240 are provided. However, the embodiments of the inventive concept are not limited thereto. According to an embodiment, a single column of rearrangement pads 240 is provided. Alternatively, three or more columns of rearrangement pads 240 are provided. According to an embodiment, a bonding wire may be arranged in various manners between a pad in a column of the rearrangement pads 240 and a pad in another column of the rearrangement pads 240.

For purposes of illustration, the power pads 210a are formed to have a ring shape. However, the embodiments of the inventive concept are not limited thereto. According to an embodiment, the power pads 210a can be formed to have various shapes such as a bonding pad shape, an ‘L’ shape, a ring shape, or a bar shape. The power pads 210a are not limited to supplying power. Locations of the bonding pads 220 or the ESC pads 230 are not limited to those described above in connection with FIG. 4. According to an embodiment, the pads 210a, 220, and 230 are positioned to have an arrangement order or locations different from those described above in connection with FIG. 4.

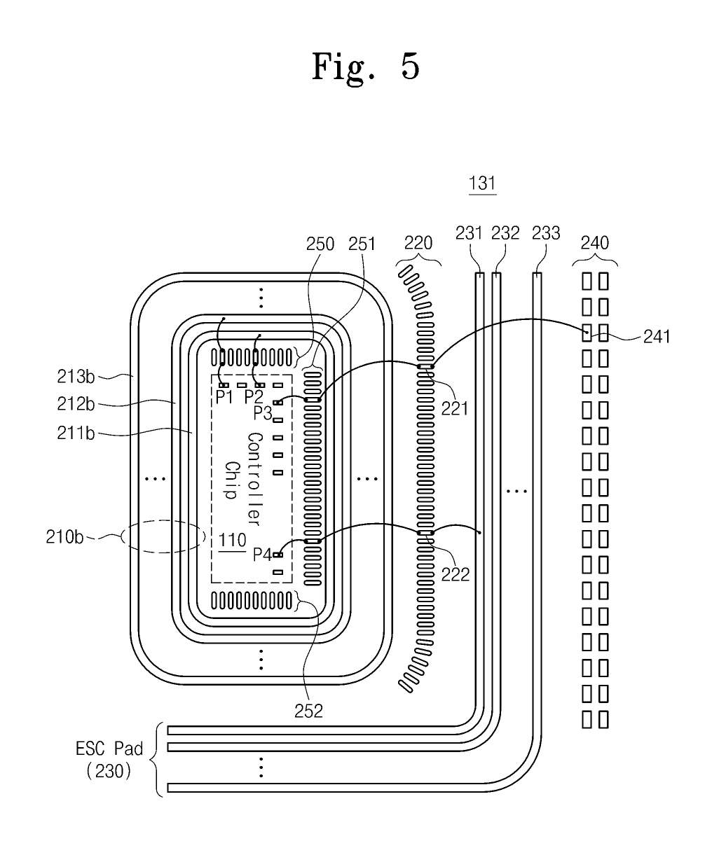

FIG. 5 is a diagram illustrating a first pad group as illustrated in FIG. 2 according to an exemplary embodiment of the inventive concept. Referring to FIG. 5, the first pad group 131 includes power pads 210b, bonding pads 220, ESC pads 230, rearrangement pads 240, and inner bonding pads 250, 251, and 252.

Through the power pads 210b, power is supplied to a controller chip 110. For example, a power supply voltage VDD or a ground voltage VSS is supplied to the controller chip via the power pads 210b. A first power pad 211b is electrically connected with a chip pad P2 of the controller chip 110 via one of the inner bonding pads 250, and a second power pad 212b is electrically connected with a chip pad P1 of the controller chip 110 via another one of the bonding pads 250. According to an embodiment, more power pads, such as a power pad 213b, may be provided.

Among the bonding pads 220, a pad 221 connected with a pad 241 of the rearrangement pads 240 via a bonding wire is connected with a chip pad P3 via one of the inner bonding pads 251. A bonding pad 222 connected with the ESC pad 231 is connected with a chip pad P4 via another one of the inner bonding pads 251. The inner bonding pads 250, 251, and 252 formed in various directions can provide flexibility or compatibility with various sizes of the controller chip 110. Further, use of the inner bonding pads 250, 251, and 252 can reduce a length of a bonding wire, thus increasing the reliability of a package.

For purposes of illustration, ring-shaped power pads 210b are provided, but the embodiments of the inventive concept are not limited thereto. According to an embodiment, the power pads 210b can be formed to have various shapes, such as a bonding pad shape, an shape, a ring shape, or a bar shape.

The bonding pads 220 are disposed between the ESC pads 230 and the controller chip 110 or between the rearrangement pads 240 and the controller chip 110. The bonding pads 220 are formed to solve a problem associated with a length of a bonding wire between the ESC pads 230 and the controller chip 110 or between the rearrangement pads 240 and the controller chip 110. For example, when the bonding wire is excessively long, the reliability of a packaging process decreases. Wire bonding can be performed together with formation of the bonding pads 220. The bonding pads 220 connect the ESC pads 230 or the rearrangement pads 240 to the chip pads (e.g., P3 or P4) in the shortest distance from chip pads.

The ESC pads 230 are extended from ESC terminals 140 as illustrated in FIG. 1. The ESC pads 230 are formed to exchange signals between an external device and the controller chip 110. The ESC pads 230 are disposed between the bonding pads 220 and the rearrangement pads 240. A pad 231 of the ESC pads 230 is connected with a pad 222 included in the bonding pads 220 via a wire. The pad 222 is electrically connected with a chip pad P4 of the controller chip 110. For purposes of illustration, electrical connection is made by one signal line. However, according to an embodiment, the connecting method also applies to the remaining pads 232 and 233 of the ESC pads 230.

The rearrangement pads 240 are connected with bonding wires extended from the bonding pads 220. For example, a pad 241 of the rearrangement pads 240 is connected with a pad 221 of the bonding pads 220 via a bonding wire. The pad 221 is electrically connected with the chip pad P3 via a bonding wire. The pad 241 is connected with any pad of a nonvolatile memory chip 120 via a PCB connection unit 135.

The rearrangement pads 240 electrically connect the controller chip 110 and the nonvolatile memory chip 120. According to an embodiment, a bonding wire for connection between the rearrangement pads 240 and the bonding pads 220 is optionally adjusted. According to an embodiment, wire bonding of the bonding pads 220 is limited by an arrangement order of chip pads P1 to P4 of the controller chip 110, and wire bonding of the rearrangement is not limited by the arrangement order of the chip pads P1 to P4. Various chip combinations can be adopted by adjusting arrangement of bonding wires between the rearrangement pads 240 and the bonding pads 220.

For purposes of illustration, two columns of rearrangement pads 240 are provided. However, the embodiments of the inventive concept are not limited thereto. According to an embodiment, a single column of rearrangement pads 240 is provided. Alternatively, three or more columns of rearrangement pads 240 are provided.

In an embodiment, the power pads 210b are not limited to supplying power. Locations of the bonding pads 220 or the ESC pads 230 are not limited to those described above in connection with FIG. 5. According to an embodiment, the pads 210b, 220, and 230 are positioned to have an arrangement order or locations different from those described above in connection with FIG. 5.

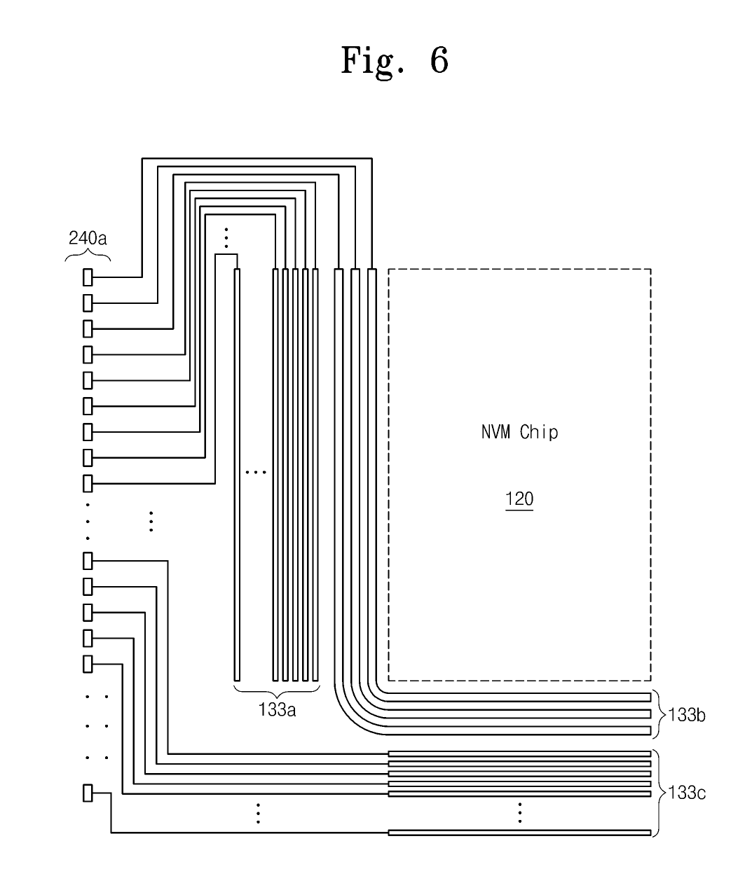

FIG. 6 is a diagram illustrating a PCB connection unit according to an exemplary embodiment of the inventive concept. The PCB connection unit 135 provides electrical connection between rearrangement pads 240a of a first pad group 110 and a second pad group 133. Referring to FIG. 6, the rearrangement pads 240a are electrically connected with all the pads, respectively, of the second pad group 133.

The rearrangement pads 240a include a column of pads, which are connected with pads 133a, 133b, and 133c of the second pad group 133 via PCB wires. The pads 133a, 133b, and 133c have various shapes. For purposes of illustration, the rearrangement pads 240a are respectively connected with the pads of the second pad group 133. However, the embodiments of the inventive concept are not limited thereto. For example, according to an embodiment, two or more pads of the rearrangement pads 240a can be electrically connected with one pad of the second pad group 133. Alternatively, one pad of the rearrangement pads 240a can be electrically connected with two or more pads of the second pad group 133.

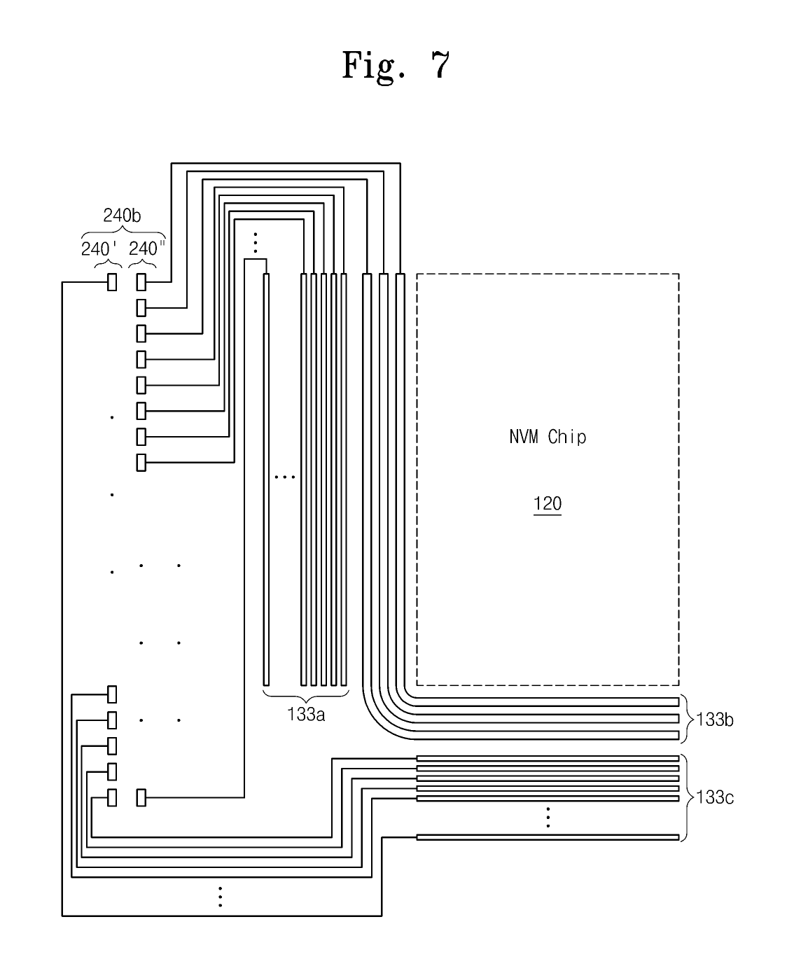

FIG. 7 is a diagram illustrating a PCB connection unit according to an exemplary embodiment of the inventive concept. Referring to FIG. 7, rearrangement pads 240b are arranged in two columns. According to an embodiment, the rearrangement pads 240b are arranged in three or more columns. Pads in each column are connected with specific pads of a second pad group 133.

Rearrangement pads 240′ in a first column are connected with second pads 133c, and rearrangement pads 240″ in a second column are connected with second pads 133a and 133b. For purposes of illustration, the second pads 133b are connected with some of the rearrangement pads 240″ of the second pad 133b. However, the embodiments of the inventive concept are not limited thereto. For example, according to an embodiment, the second pads 133b can be connected with a column of rearrangement pads other than the first and second columns. Alternatively, the second pads 133b can be connected with some of the rearrangement pads 240′.

As described in relation to FIGS. 6 and 7, the rearrangement pads 240 and the second pad group 133 can be connected to each other by various PCB wiring methods. A wiring method of the PCB connection unit 135 remains unchanged. For example, according to an embodiment, the PCB connection unit 135, once the universal PCB 130 is designed, is not subjected to additional wiring.

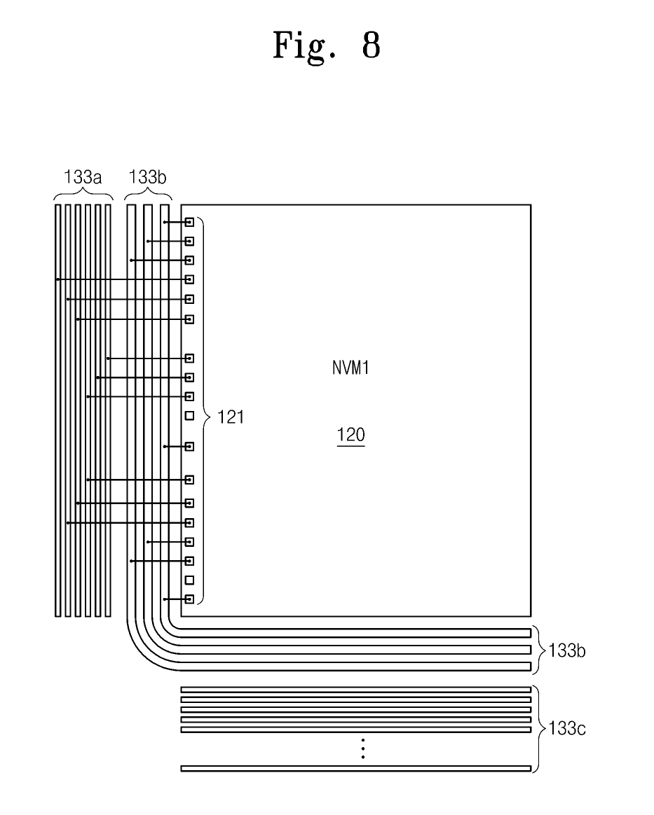

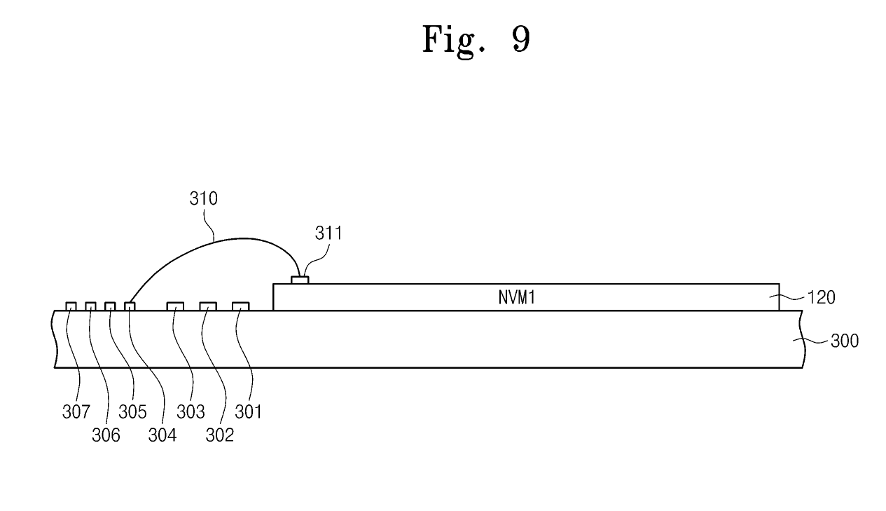

FIGS. 8 and 9 are diagrams schematically illustrating wire bonding between a nonvolatile memory chip and a second pad group according to an exemplary embodiment of the inventive concept. Referring to FIG. 8, it is described that one nonvolatile memory chip 120 is mounted on a PCB via one input/output channel. FIG. 8 illustrates connections between the nonvolatile memory chip 120 and the second pad group 133 via wires.

The second pad group 133 includes pads which have various shapes and various directions. For example, the second pad group 133 includes pads 133a and 133b. The pads 133a are arranged in a direction perpendicular to an arrangement direction of chip pads 121 of the nonvolatile memory chip 120. The pads 133b have an L shape. Pads 133c of the second pad group 133 are not connected with the chip pads 121. For example, according to an embodiment, the pads 133a and 113b may be sufficient for connection between the nonvolatile memory chip 120 and the controller chip 110 via one input/output channel.

FIG. 9 illustrates a cross sectional view of a region illustrated in FIG. 8. A plurality of pads 301 to 307 are formed on a PCB substrate 300. A nonvolatile memory chip 120 including a chip pad 311 is mounted on the PCB substrate 300.

The pads 301 to 307 respectively correspond to some of the pads 133a and 133b shown in FIG. 8. The pad 311 formed on the nonvolatile memory chip 120 is one of the chip pads 121 shown in FIG. 8. The chip pad 311 is connected with a pad 304 formed on the PCB substrate 300 by a bonding wire 310. However, the chip pad 311 can be connected with at least one of the pads 301 to 307 on the PCB substrate 200.

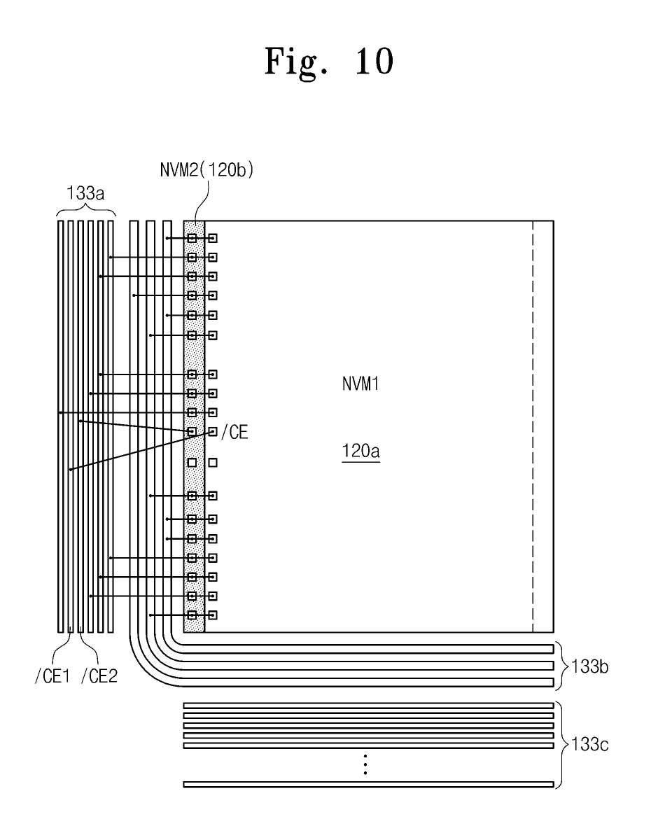

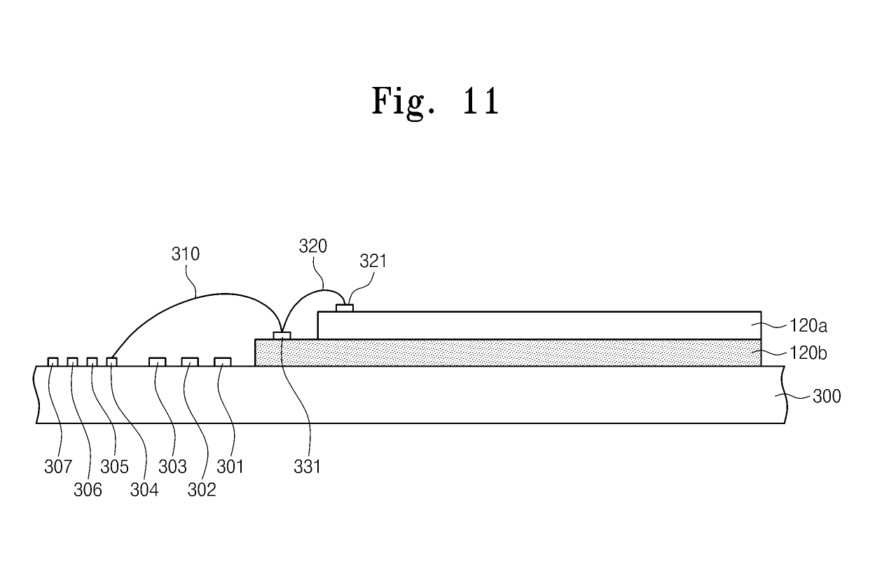

FIGS. 10 and 11 are diagrams schematically illustrating a wire bonding method and a second pad group according to a mounting type of a nonvolatile memory chip 120. Referring to FIG. 10, nonvolatile memory chips 120a and 120b having the same type are stacked on a PCB substrate in the same dimension.

The lower nonvolatile memory chip 120b and the upper nonvolatile memory chip 120a have the same chip pad arrangement. Input/output pads or control signal pads of the nonvolatile memory chips 120a and 120b are connected to be shared by wires. A selection signal pad, such as a chip enable signal pad /CE, is driven separately for two memory chips to share one channel. Accordingly, a chip enable signal pad /CE of the upper nonvolatile memory chip 120a is wire bonded with a first chip enable signal pad /CE1 of pads 133a. A chip enable signal pad /CE of the lower nonvolatile memory chip 120b is wire bonded with a second chip enable signal /CE2 of the pads 133a.

For purposes of illustration, two nonvolatile memory chips 120a and 120b sharing one channel are stacked. However, the embodiments of the inventive concept are not limited thereto. According to an embodiment, three or more nonvolatile memory chips sharing one channel are stacked in the same dimension.

FIG. 11 is a diagram schematically illustrating a cross sectional view of a region illustrated in FIG. 10. A plurality of pads 301 to 307 are formed on a PCB substrate 300. Nonvolatile memory chips 120a and 120b including chip pads 321 and 331 with the same function are stacked on the PCB substrate 300.

The pads 301 to 307 illustrated in FIG. 11 correspond to some of the pads 133a and 133b shown in FIG. 10. The pad 321 formed on the nonvolatile memory chip 120a is connected with the pad 331 formed on the nonvolatile memory chip 120b via a wire 320. The pad 331 is connected with a pad 304 formed on the PCB substrate 300 via a wire 310. Chip pads with the same function of each of the nonvolatile memory chips 120a and 120b are shared. According to an embodiment, chip pads corresponding to a chip enable signal /CE, an address signal ADD, and a ready/busy signal RnB of each of the nonvolatile memory chips 120a and 120b are not shared.

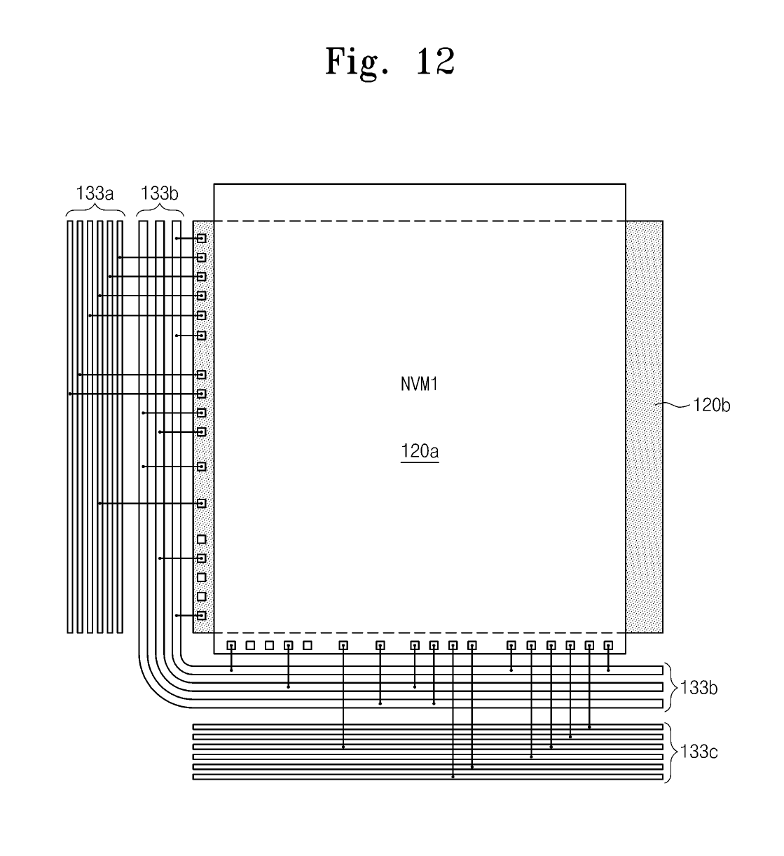

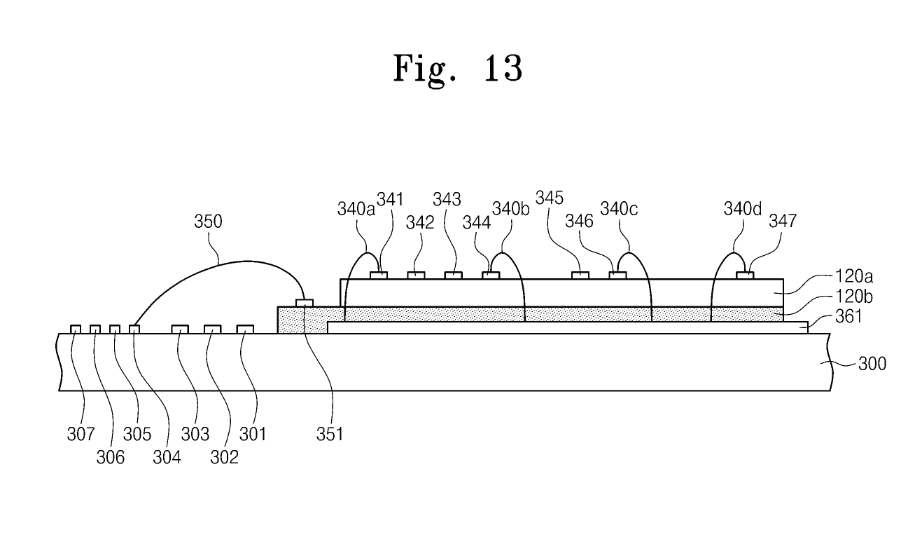

FIGS. 12 and 13 are diagrams schematically illustrating a second pad 133 and a wire bonding method according to a mounting type of nonvolatile memory chips. Referring to FIG. 12, nonvolatile memory chips 120a and 120b with the same type are stacked on a PCB substrate in different dimensions.

A lower nonvolatile memory chip 120b and an upper nonvolatile memory chip 120a have the same chip pad arrangement. However, according to an embodiment, the nonvolatile memory chips 120a and 120b can be stacked such that chip pads are arranged in different directions. For example, the nonvolatile memory chip 120b is mounted such that chip pads are easily wire bonded with pads 133a and 133b. The nonvolatile memory chip 120a is mounted such that chip pads are easily wire bonded with pads 133c and 133d.

The pads 133b including power pads have an ‘L’ shape for power-related pads of each of the nonvolatile memory chips 120a and 120b. However, for connection with a controller chip 110 via different channels, the pads 133a are wire bonded with chip pads of the nonvolatile memory chip 120b. The pads 133c are wire bonded with chip pads of the nonvolatile memory chip 120a. As described above, the nonvolatile memory chips 120a and 120b are configured to be connected with the controller chip 110 via two input/output channels.

For purposes of illustration, two nonvolatile memory chips 120a and 120b for connection with two input/output channels are stacked. However, the embodiments of the inventive concept are not limited thereto. According to an embodiment, three or more nonvolatile memory chips, to which three or more input/output channels are independently assigned, are stacked in different dimensions.

Referring to FIG. 13, which is a cross sectional view of a region illustrated in FIG. 12, a plurality of pads 301 to 307 for wire bonding with chip pads of the nonvolatile memory chip 120b are formed on a PCB substrate 300. The pads 301 to 303 which are shaped as L can be connected with a chip pad of the nonvolatile memory chip 120a. A plurality of pads 361 for wire bonding with chip pads of the nonvolatile memory chip 120a are formed on the PCB substrate 300. The pads 361 each have a bar type, and one pad 361 is illustrated in FIG. 13.

The pads 301 to 307 correspond to some of pads 133a and 133b shown in FIG. 12. A chip pad 351 included in the nonvolatile memory chip 120b is connected with a pad 304 formed on the PCB substrate 300 via a bonding wire 350. The nonvolatile memory chip 120a can be stacked on the nonvolatile memory chip 120b in a different direction. The nonvolatile memory chip 120a includes chip pads 341 to 347. Some pads 341, 344, 346, and 347 are connected with pads 361 via bonding wires 340a, 340b, 340c, and 340d, respectively.

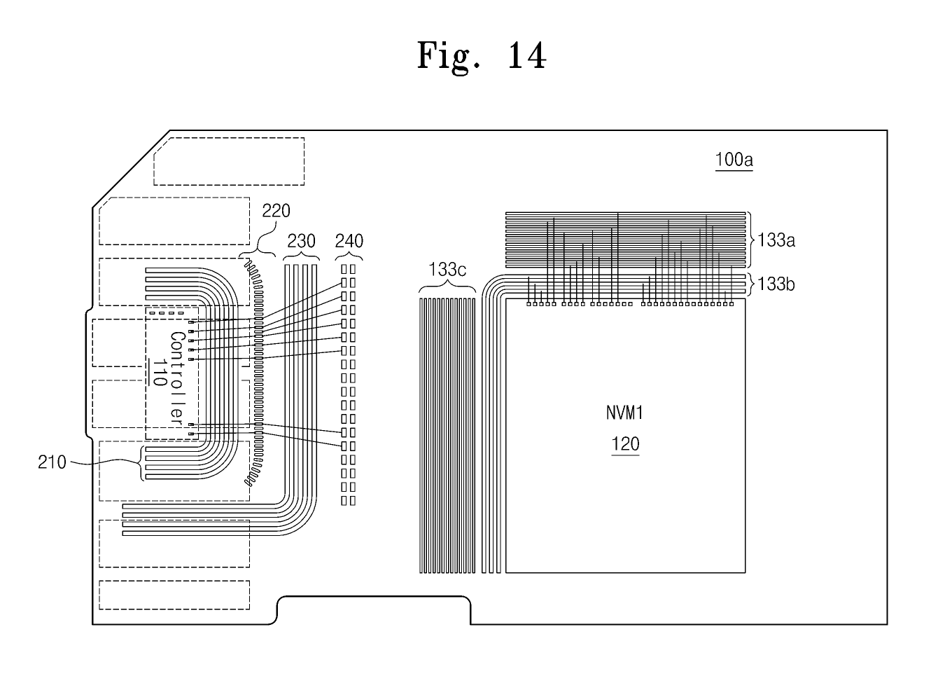

FIGS. 14 to 16 are diagrams illustrating applicable examples of a universal PCB technique according to a mounting condition of a nonvolatile memory chip.

Referring to FIG. 14, a memory card 100a includes a controller chip 110 and a single nonvolatile memory chip 120. The controller chip 110 and the nonvolatile memory chip 120 exchange data and control signals via a single channel. The memory card 100a includes power pads 210, bonding pads 220, ESC pads 230, and rearrangement pads 240 in a first pad group 131. The first pad group 131 is included in a universal PCB 130 as illustrated in FIG. 1. The memory card 110a includes pads 133a, 133b, and 133c in a second pad group 133. The second pad group 133 is included in the universal PCB 130.

According to an embodiment, the rearrangement pads 240 and the pads 133a, 133b, and 133c of the second pad group 133 are electrically connected via a PCB wire of a PCB connection unit 135 as illustrated in FIG. 2. When a controller chip 110 and a single nonvolatile memory chip are mounted on the universal PCB according to an exemplary embodiment of the inventive concept, a utilization rate of the bonding pad 220 and the rearrangement pad 240 is relatively low. For example, the number of bonding wires for connecting chip pads of the controller chip 110 with the bonding pads 220 and the number of bonding wires for connecting the bonding pads 220 with the rearrangement pads 240 are relatively small, e.g., since a single nonvolatile memory chip is mounted. Accordingly, pads 133c formed in a different direction from a chip pad of the nonvolatile memory chip 120 may not be used.

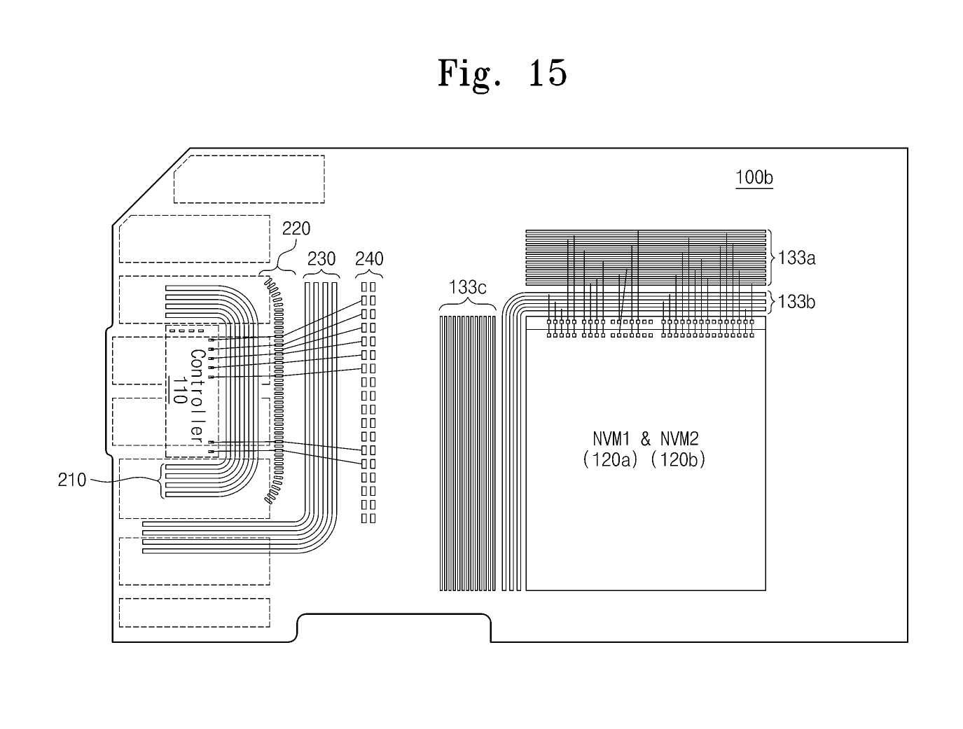

Referring to FIG. 15, a memory card 100b includes a controller chip 110 and multiple nonvolatile memory chips 120a and 120b. The controller chip 110 and the nonvolatile memory chips 120a and 120b exchange data and control signals via a single channel. The memory card 110b includes power pads 210, bonding pads 220, ESC pads 230, and rearrangement pads 240 in the first pad group 131 included in the universal PCB 130. The memory card 110b includes pads 133a, 133b, and 133c in the second pad group 133 included in the universal PCB 130.

According to an embodiment, the rearrangement pads 240 and the pads 133a, 133b, and 133c of the second pad group 133 are electrically connected via a PCB wire of a PCB connection unit 135 as illustrated in FIG. 2. The nonvolatile memory chips 120a and 120b with the same type are stacked in the same dimension. A lower nonvolatile memory chip 120b and an upper nonvolatile memory chip 120a have the same pad arrangement. Accordingly, the pads including an input/output pad and a control signal pad can be wire bonded to be shared.

A chip enable signal /CE is driven independently such that two memory chips share one channel Accordingly, chip enable pads /CE of the nonvolatile memory chips 120a and 120b are wire bonded with different pads 133a.

When the controller 110 and the multiple nonvolatile memory chips 120a and 120b are mounted on a universal PCB 130 (refer to FIG. 1), a wire bonding method between pads is changed. The nonvolatile memory chips 120a and 120b and the controller chip 110 can be connected to each other via the universal PCB 130 according to an exemplary embodiment of the inventive concept. According to an embodiment, the number of chip pads shared between the nonvolatile memory chips 120a and 120b increases, and similar bonding wire connections can be thus made as shown in FIGS. 14 and 15. For example, the number of bonding wires needed when multiple nonvolatile memory chips are mounted is the same or substantially the same as the number of bonding wires needed when a single nonvolatile memory chip is mounted.

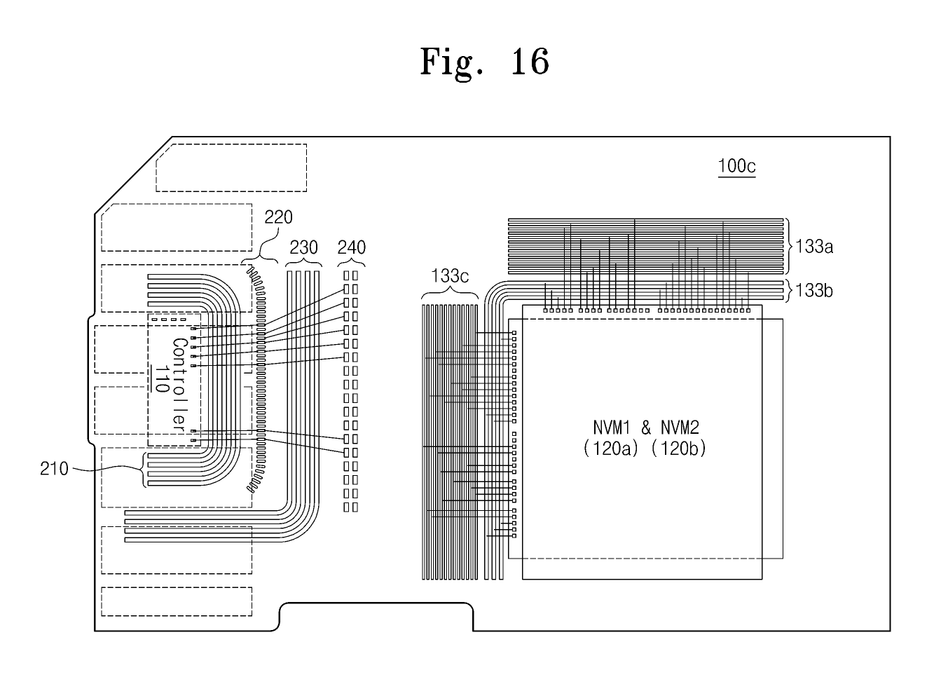

Referring to FIG. 16, a memory card 100c includes a controller chip 110 and multiple nonvolatile memory chips 120a and 120b. The nonvolatile memory chips 120a and 120b exchange data and control signals with the controller chip 110 via different channels. The memory card 110c includes power pads 210, bonding pads 220, ESC pads 230, and rearrangement pads 240 in the first pad group 131. The first pad group 131 is included in the universal PCB 130. The memory card 110b includes pads 133a, 133b, and 133c in the second pad group 133. The second pad group 133 is included in the universal PCB 130.

According to an embodiment, the rearrangement pads 240 and the pads 133a, 133b, and 133c of the second pad group 133 are electrically connected via a PCB wire of a PCB connection unit 135 as illustrated in FIG. 2. The nonvolatile memory chips 120a and 120b are stacked in different dimensions. A lower nonvolatile memory chip 120b is connected with the pads 133b and 133c via wires. An upper nonvolatile memory chip 120a is connected with the pads 133a and 133b via wires. The number of wires connected with chip pads increases when the nonvolatile memory chips 120a and 120b are connected with the controller chip 110 via different channels. The number of wires for connecting a controller chip 110 with pads 210, 220, 230, and 240 formed around the controller chip 110 also increases.

Although the controller 110 and the multiple nonvolatile memory chips 120a and 120b are mounted on a universal PCB 130 as shown in FIG. 1, it is the wire bonding method between pads that changes. For example, the memory card 100c including the nonvolatile memory chips 120a and 120b and the controller chip 110 can be configured by the universal PCB 130 identical to that illustrated in FIG. 14.

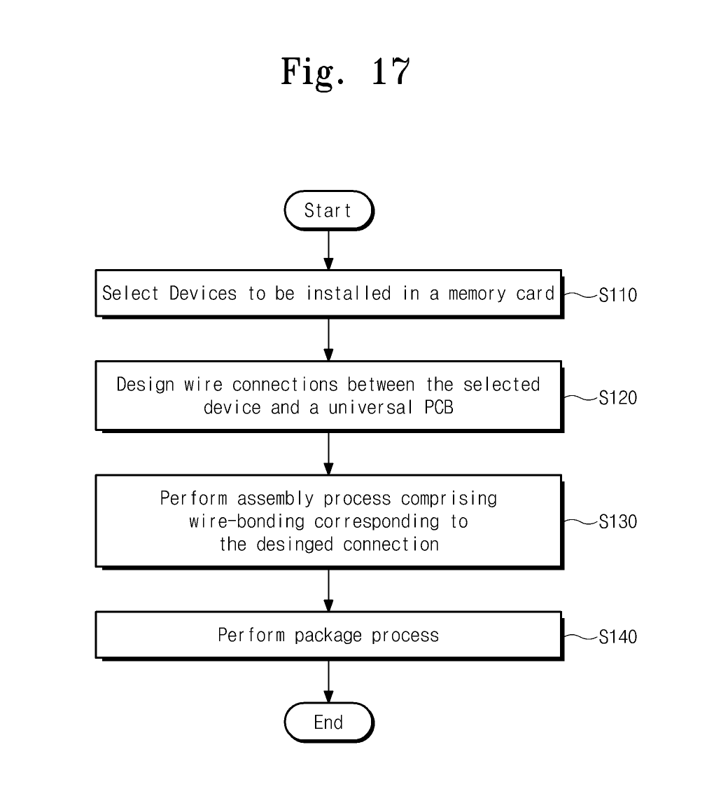

FIG. 17 is a flowchart for describing a memory card fabricating process according to an exemplary embodiment of the inventive concept. Referring to FIG. 17, use of a universal PCB 130 according to an exemplary embodiment of the inventive concept enables a memory card to include various device combinations without separate PCB design.

In step S110, devices to be mounted in a memory card 100 are selected. For example, a nonvolatile memory device and a memory controller are selected. When a universal PCB 130 is used, selection is not limited by compatibility with PCB.

In step S120, bonding wires are designed for electrical connection between the selected devices and the universal PCB 130. The universal PCB 130 is compatible with various devices through design of bonding wires.

In step S130, the selected devices are mounted and installed on the universal PCB 130. Wire bonding between the universal PCB and the devices is made by a previously designed method. Further, wire bonding between pads on the universal PCB 130 is made according to the previously designed method. Electrical connection which is not rearranged between chip pads of a device and the universal PCB 130 can be rearranged by wire bonding between bonding pads 220 and rearrangement pads 240.

In step 140, the wire bonded devices and the universal PCB are packaged within a case of a memory card shape.

According to an embodiment, without the need of designing and making a separate PCB corresponding to a selected device to be mounted in a memory card, the memory card can be manufactured by changing wire connection between the universal PCB and the selected device, thus simplifying the fabricating process.

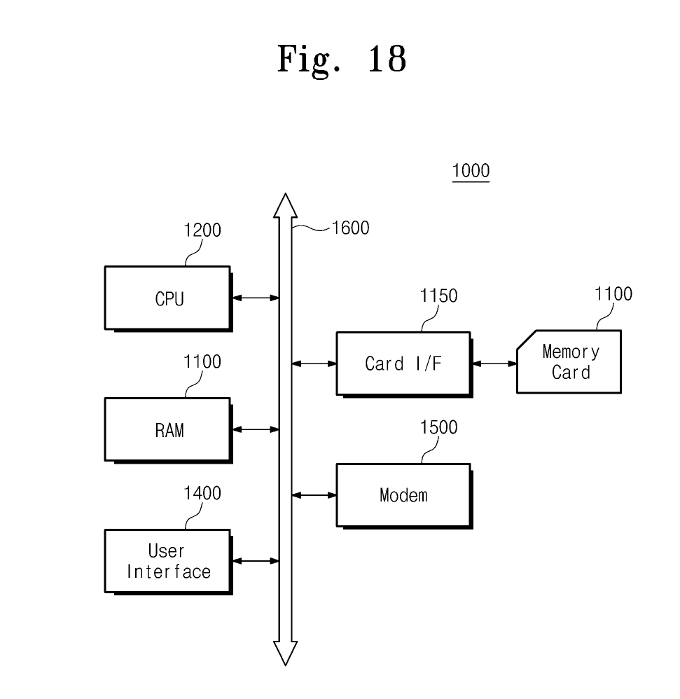

FIG. 18 is a diagram schematically illustrating a computing system including a memory card according to an exemplary embodiment of the inventive concept. A computing system 1000 includes a CPU 1200, a RAM 1100, a user interface 1400, a modem 1500, such as a baseband chipset, a card interface 1150, and a memory card 1100. The elements 1100, 1200, 1400, 1500, and 1150 are electrically connected with a system bus 1600.

When the computing system 1000 is a mobile device, a battery is further provided to power the computing system 100. According to an embodiment, the computing system further includes an application chipset, a camera image processor (CIS), or a mobile DRAM.

The embodiments are to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

What is claimed is:

1. A memory card comprising:
a printed circuit board (PCB) including,
a first pad group having a plurality of pads;
a second pad group having a plurality of pads; and
a PCB wire connecting the first pad group with the second pad group;
a first bonding wire connecting a pad of a first semiconductor chip of a first type with one of the plurality of pads of the first pad group or connecting a pad of a second semiconductor chip of a second type with another pad of the plurality of the first pad group, wherein the first type is different from the second type; and
a second bonding wire connecting a pad of a third semiconductor chip of a third type with one of the plurality of pads of the second pad group.

2. The memory card of claim 1, wherein the second bonding wire connects a pad of a fourth semiconductor chip of a fourth type with another pad of the plurality of pads of the second pad group, wherein the third type is different from the fourth type.

3. The memory card of claim 1, wherein the first pad group comprises:
at least one power pad through which power is supplied to the first or second semiconductor chip;
an external signal connection pad through which a signal is provided from a host to the first or second semiconductor chip; and
a rearrangement pad through which the pad of the first or second semiconductor chip is connected to the PCB wires.

4. The memory card of claim 3, wherein the first pad group further comprises:
a first bonding pad formed between the first or second semiconductor chip and the external signal connection pad or between the first or second semiconductor chip and the rearrangement pad.

5. The memory card of claim 4, wherein the first bonding pad is wire bonded with the pad of the first or second semiconductor chip and the external signal connection pad or at least one pad of the rearrangement pads.

6. The memory card of claim 4, further comprising:
a second bonding pad connected with the first bonding pad and the pad of the first or second semiconductor chip via a bonding wire.

7. The memory card of claim 6, wherein the second bonding pad is closer to the first or second semiconductor chip than the power pad.

8. The memory card of claim 3, wherein the power pad is formed to surround the first or second semiconductor chip.

9. The memory card of claim 3, wherein the power pad has at least one of a ring shape, a bar shape, a C shape, an L shape, or a bonding pad shape.

10. The memory card of claim 1, wherein the pads of the second pad group comprises:
one or more first pads formed at a first side of the third semiconductor chip;
one or more second pads formed at a second side of the third semiconductor chip; and
one or more third pads formed at the first and second sides of the third semiconductor chip.

11. The memory card of claim 10, wherein the third pads have an L shape.

12. The memory card of claim 10, wherein the third semiconductor chip includes a single chip and is electrically connected with the first and third pads via one or more wires.

13. The memory card of claim 10, wherein the third semiconductor chip includes a multi-chip and is electrically connected with the first and third pads via one or more wires.

14. The memory card of claim 13, wherein the multi-chip includes sub chips with the same type and is configured to exchange a signal with the first or second semiconductor chip via an input/output channel, and wherein data pads of the multi-chip are mutually shared.

15. The memory card of claim 10, wherein the third semiconductor chip includes a multi-chip having first and second sub chips with the same type, the first and second sub chips stacked in different dimensions, wherein the first sub chip of the multi-chip is electrically connected with the first and third pads via one or more wires, and the second sub chip of the multi-chip is electrically connected with the second and third pads via one or more wires.

16. The memory card of claim 1, wherein the third semiconductor chip includes a nonvolatile memory chip, and the first or second semiconductor chip includes a controller chip, the controller chip configured to control the nonvolatile memory chip.

17. A printed circuit board comprising:
a first pad group having a plurality of pads;
a second pad group having a plurality of pads;
a printed circuit board (PCB) connection unit connecting the first pad group with the second pad group;
a first bonding wire connecting a pad of a first semiconductor chip of a first type with one of the plurality of pads of the first pad group or connecting a pad of a second semiconductor chip of a second type with another pad of the plurality of pads of the first pad group, wherein the first type is different from the second type; and
a second bonding wire connecting a pad of a third semiconductor chip of a third type with one of the plurality of pads of the second pad group.

18. The printed circuit board of claim 17, wherein the first pad group includes an external signal connection pad configured to exchange a signal between the first or second semiconductor chip and an external device.

19. A printed circuit board (PCB) comprising:
a first pad group including first and second bonding pads;
a second pad group; and
a PCB wire connecting the first pad group with the second pad group, wherein when a first chip has a first type, a pad of the first chip is wire-bonded to the first bonding pad, and when the first chip has a second type, the pad of the first chip is wire-bonded to the second bonding pad.

20. The printed circuit board (PCB) of claim 19, wherein the second pad group includes first and second bonding pads, wherein when a second chip has a first type, a pad of the second chip is wire-bonded to the first bonding pad of the second pad group, and when the second chip has a second type, the pad of the second chip is wire-bonded to the second bonding pad of the second pad group
